(19) United States
(12) Patent Application Publication
(10) Pub. No.: US 2026/0057950 A1
(43) Pub. Date: Feb. 26, 2026

(54) MEMORY DEVICE FOR CONTROLLING SLEW RATE AND METHOD THEREFOR

(71) Applicant: Winbond Electronics Corp., Taichung City (TW)

(72) Inventor: Chia-Lung Hsieh, Hsinchu (TW)

(73) Assignee: Winbond Electronics Corp., Taichung City (TW)

(21) Appl. No.: 19/257,427

(22) Filed: Jul. 1, 2025

(30) Foreign Application Priority Data
Aug. 22, 2024 (TW) 113131577

(51) Int. Cl. G11C 29/02; G11C 11/4076; G11C 11/4093

(52) U.S. Cl. CPC G11C 29/028; G11C 11/4076; G11C 11/4093; G11C 2207/2254

(57) ABSTRACT

A memory device and a method for controlling slew rate are disclosed. The memory device includes a memory array, a slew rate control circuit, and an output stage circuit. The memory array provides a data signal. The slew rate control circuit includes multiple pre-drivers. The slew rate control circuit receives a ZQ calibration signal and adjusts driving strength of each of the pre-drivers in the slew rate control circuit according to the ZQ calibration signal. The pre-drivers are configured to generate a driven enable signal according to the data signal. The output stage circuit generates a data voltage signal based on the driven enable signal and the data signal. The slew rate of the data voltage signal is adjusted based on the driving strength of the pre-drivers.

### CROSS-REFERENCE TO RELATED APPLICATION

This application claims the priority benefit of Taiwan application serial no. 113131577, filed on Aug. 22, 2024. The entirety of the above-mentioned patent application is hereby incorporated by reference herein and made a part of this specification.

### BACKGROUND

### Technical Field

The disclosure relates to a semiconductor memory technology, and particularly relates to a semiconductor memory device that uses a ZQ calibration signal to control and compensate for a slew rate (SR) and a method thereof.

### Description of Related Art

An output stage circuit of a double data rate memory device needs to meet industry specifications for DC and AC. Since a component size of the output stage circuit is determined at a DC stage, an AC output of the output stage circuit is controlled through a slew rate control circuit.

The output stage circuit itself is affected by process, voltage and temperature (referred to as “PVT”) variations, resulting in variation of a driving strength, and under a certain circumstance (for example, a high voltage, a fast-fast (FF) corner based on boundary corner analysis), the slew rate may be too strong and may affect an EMI measurement result on system, or under another circumstance (for example, a low voltage, a slow-slow (SS) corner based on boundary angle analysis), the slew rate may be too small, resulting in attenuation of a data effective window.

In a third-generation double data rate (DDR3) memory device and subsequent generations of memory devices, although ZQ calibration has been used to reduce the variation in driving strength, the slew rate control circuit implemented based on adjusting a delay time may still generate additional current consumption and may still be affected by different P, V, and T variations. Therefore, to reduce a delay time variation of the slew rate control circuit is one of the directions to solve the problem.

### SUMMARY

The disclosure is directed to a memory device for controlling slew rate and a method thereof, which adjust driving strength of pre-drivers according to a ZQ calibration signal, compensate for a delay time of a data voltage signal serving as an output, and thereby reduce variation of a slew rate of the output signal in the delay time.

The memory device of the disclosure includes a memory array, a slew rate control circuit, and an output stage circuit. The memory array is configured to provide a data signal. The slew rate control circuit is coupled to the memory array, and includes multiple pre-drivers. The slew rate control circuit receives a ZQ calibration signal and adjusts a driving strength of each of the pre-drivers in the slew rate control circuit according to the ZQ calibration signal. The pre-drivers are configured to generate a driven enable signal according to the data signal. The output stage circuit is coupled to the slew rate control circuit. The output stage circuit generates a data voltage signal according to the driven enable signal and the data signal. A slew rate of the data voltage signal is adjusted based on the driving strength of the pre-drivers.

The disclosure provides a method for controlling slew rate, which is configured to adjust a slew rate of a data voltage signal applied to memory units with different PVT characteristics. The method includes the following. A ZQ calibration signal is received for impedance compensation. A driving strength of each of multiple pre-drivers in a slew rate control circuit is adjusted according to the ZQ calibration signal. The pre-drivers are configured to generate a driven enable signal based on a data signal provided by a memory array. A data voltage signal is generated through an output stage circuit according to the driven enable signal and the data signal. A slew rate of the data voltage signal is adjusted based on the driving strength of the pre-drivers.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic diagram of a memory device according to an embodiment of the disclosure.

FIG. 2 is a circuit block diagram of a slew rate control circuit and an output stage circuit according to an embodiment of the disclosure.

FIG. 3 is a flowchart illustrating a method of controlling slew rate according to an embodiment of the disclosure.

### DESCRIPTION OF THE EMBODIMENTS

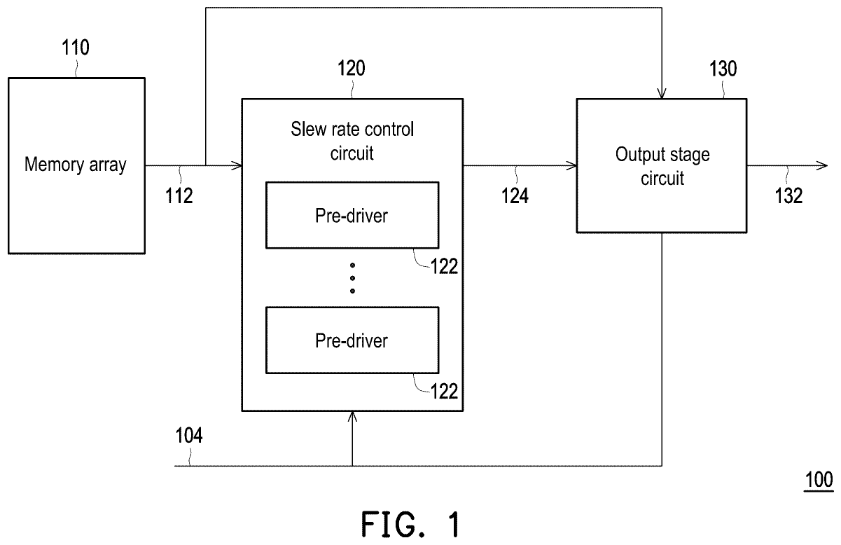

FIG. 1 is a schematic diagram of a memory device 100 according to an embodiment of the disclosure. As shown in FIG. 1, the memory device 100 includes a memory array 110, a slew rate (SR) control circuit 120 and an output stage circuit 130. In the embodiment, the memory device 100 may be a third-generation double data rate (DDR3) memory device, a fourth-generation double data rate (DDR4) memory device, or other memory devices with ZQ calibration signals.

The memory array 110 includes one or multiple memory blocks, and each memory block includes multiple memory units arranged in an array. The memory array 110 may be a dynamic random access memory (DRAM), a static random access memory (SRAM), or any other type of memory (including those that do not require refreshing). The memory array 110 may include multiple channels of memory such as synchronous DRAM (SDRAM). The SDRAM may be a double data rate (DDR) memory. The disclosure is not limited to the above memory types. In an embodiment, each memory array may be coupled to the corresponding output stage circuit 130 through a memory controller (not shown). The memory array is configured to provide a data signal 112. In the embodiment, the data signal 112 is read from the memory array 110 and output as a data voltage signal 132 by the output stage circuit 130.

The SR control circuit 120 is coupled to the memory array 110 and the output stage circuit 130. The SR control circuit 120 respectively receives the data signal 112 and a ZQ calibration signal 104. The SR control circuit 120 includes multiple pre-drivers 122. The pre-drivers 122 are configured to generate a driven enable signal 124 based on the data signal 112. The SR control circuit 120 receives the ZQ calibration signal 104 and adjusts respective driving strength of the plurality of pre-drivers in the SR control circuit 120 according to the ZQ calibration signal 104. The output stage circuit 130 is coupled to the SR control circuit 120 and the memory array 112. The output stage circuit 130 generates a data voltage signal 132 based on the driven enable signal 124 and the data signal 112. A slew rate of the data voltage signal 132 is adjusted based on the driving strength of the pre-drivers 122.

Specifically, the ZQ calibration signal 104 is generally configured to compensate for impedance variation of the output stage circuit 130 caused by PVT variation (also referred to as PVT characteristics). For example, the ZQ calibration signal 104 may be configured to adjust resistances of pull-up and pull-down resistors (not shown) in the output stage circuit 130 according to a resistance of an on-die termination (ODT) resistor during the PVT variation. Therefore, the ZQ calibration signal 104 reflects effects caused by the PVT variation.

In the embodiment, a slew rate (also referred to as an output slew rate) of the data voltage signal 132 output by the output stage circuit 130 is adjusted through a relationship between the ZQ calibration signal 104 and the driving strength of the pre-drivers 122. In detail, the SR control circuit 120 mainly delays enabling an output buffer in the output stage circuit 130 by a delay time to accordingly adjust the slew rate. Therefore, when the delay time varies due to the influence of the PVT variation, in the embodiment, the existing ZQ calibration signal in the third-generation double data rate (DDR3) memory device and subsequent generations of memory devices is used to enhance or weaken signal strength of the output buffer in the output stage circuit 130 under different PVT characteristics, so as to decrease or increase the circuit delay time, and accordingly compensate for the variation of the slew rate. Moreover, since the embodiment changes the delay time by changing the driving strength of the pre-drivers to compensate for the variation of the slew rate, instead of adjusting parameters of components on a resistor-capacitor (RC) delay circuit inside the control circuit, no additional current consumption may be generated, which may save more power.

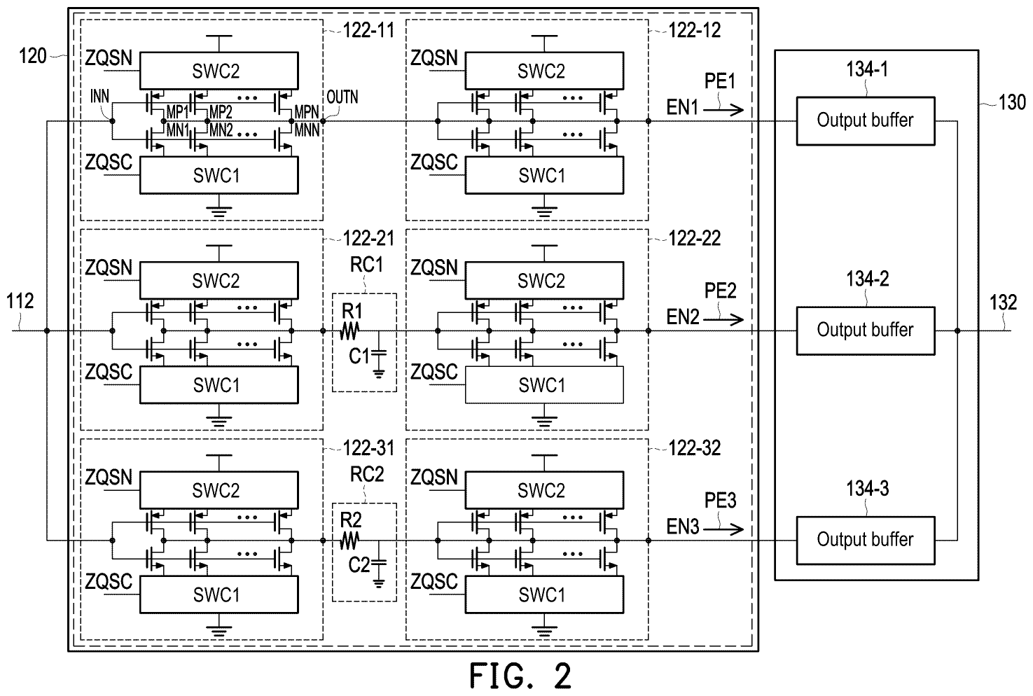

The ZQ calibration signal 104 of the embodiment may have N+1 bits. For example, the ZQ calibration signal 104 may also be referred to as a ZQ calibration code ZQC<N:0>, where N is a positive integer. In the embodiment, the slew rate is compensated based on a predetermined relationship between the ZQ calibration signal and the driving strength of the pre-drivers. In a practical application, considering that a number of bits of the ZQ calibration signal 104 may be large to make the impedance calibration more precise, the SR control circuit 120 of the embodiment uses other signals in the ZQ calibration signal 104 except a least significant bit (LSB) as an adjusted ZQ calibration signal (for example, adjusted ZQ calibration signal ZQC<N:1>) to adjust the respective driving strength of the pre-drivers 122 in the SR control circuit 120. The above approach may also reduce increase in a chip area caused by an excessively large total size of transistors in the pre-drivers due to too fine differentiation of the driving strength. In FIG. 2, the adjusted ZQ calibration signal ZQC<N:1> is presented through an adjusted ZQ calibration signal ZQSC.

In the embodiment, the SR control circuit 120 further includes a resistor-capacitor (RC) delay circuit in addition to the pre-drivers 122. A relationship between sizes of the transistors in the pre-drivers 122, a size of the RC delay circuit and the ZQ calibration signal ZQC<N:1> may be learned based on experiments or computer simulation results, and may be realized in the SR control circuit 120 through a lookup table or corresponding logic circuits. For example, the fast-fast (FF) corner and the slow-slow (SS) corner based on boundary angle analysis are targets, the driving strength required by the output stage circuit 130 under these two corners is used as a result, and through a level change of the pre-drivers corresponding to the ZQ calibration signal ZQC<N:1>, a change value of each level of the driving strength in the pre-drivers is adjusted, thereby adjusting the delay time of delaying enabling of the output stage circuit 130, so as to achieve compensation of the slew rate.

FIG. 2 is a circuit block diagram of the SR control circuit 120 and the output stage circuit 130 according to an embodiment of the disclosure. The SR control circuit of the embodiment includes at least one enable signal path, and the output stage circuit 130 includes at least one output buffer. The number of the enable signal paths and the number of the output buffers are the same. As shown in FIG. 2, the SR control circuit 120 includes three enable signal paths PE1-PE3, and the output stage circuit 130 includes three output buffers 134-1 to 134-3. Each of the enable signal paths PE1-PE3 receives the data voltage signal 112 and provides corresponding plurality of driven sub-enable signals EN1-EN3. In the embodiment, the driven sub-enable signals EN1-EN3 in FIG. 2 serve as the driven enable signal 124 in FIG. 1.

The output stage circuit 130 includes multiple output buffers (for example, three output buffers 134-1 to 134-3). The output buffers 134-1 to 134-3 receive the corresponding driven sub-enable signals EN1-EN3 to generate multiple sub-data voltage signals, and these sub-data voltage signals serve as the data voltage signal 132.

Each enable signal path includes a first pre-driver and a second pre-driver connected in series. For example, the enable signal path PE1 in FIG. 2 includes a first pre-driver 122-11 and a second pre-driver 122-12 connected in series; the enable signal path PE2 includes a first pre-driver 122-21 and a second pre-driver 122-12 connected in series; the enable signal path PE3 includes a first pre-driver 122-31 and a second pre-driver 122-32 connected in series. Circuit structures of the first pre-drivers 122-11 to 122-31 and the second pre-drivers 122-12 to 122-32 are the same.

The first pre-driver 122-11 is used as an example to illustrate the circuit structure of each pre-driver in the SR control circuit 120. The first pre-driver 122-11 includes an input terminal INN, an output terminal OUTN, multiple first type transistors (for example, N-type transistors) MN1-MNN, a first switching circuit SWC1, multiple second type transistors (for example, P-type transistors) MP1-MPN and a second switching circuit SWC2.

Control terminals (for example, gate terminals) of the first type transistors MN1-MNN are coupled to the input terminal INN. First terminals (for example, drain terminals) of the first type transistors MN1-MNN are coupled to the output terminal OUTN. Sizes of the first type transistors MN1-MNN are different from each other. In the embodiment, the sizes of the first type transistors MN1-MNN may be designed to be 1:2:4 . . . :n, where n is a positive integer. A control terminal of the first switching circuit SWC1 is coupled to the adjusted ZQ calibration signal ZQSC. A first terminal of the first switching circuit SWC1 is coupled to a reference voltage terminal (for example, a ground terminal). A second terminal of the first switching circuit SWC1 is coupled to second terminals (for example, source terminals) of the first type transistors MN1-MNN.

First terminals (for example, drain terminals) of the second type transistors MP1-MPN are coupled to the output terminal OUTN. Sizes of the second type transistors MP1-MPN are different from each other. In the embodiment, the sizes of the second type transistors MP1-MPN may be designed to be 1:2:4 . . . :n, where n is a positive integer. A control terminal of the second switching circuit SWC2 is coupled to an inverted adjusted ZQ calibration signal ZQSN. A first terminal of the second switching circuit SWC2 is coupled to an operating voltage terminal. A second terminal of the second switching circuit SWC2 is coupled to second terminals (for example, source terminals) of the second type transistors MP1-MPN.

The SR control circuit 120 of FIG. 2 uses the adjusted ZQ calibration signal ZQSC to selectively conduct the first transistors MN1-MNN in the first pre-driver 122-11 to the reference voltage terminal. Namely, the first switching circuit SWC1 selectively turns on one or a combination of the first type transistors MN1-MNN according to the adjusted ZQ calibration signal ZQSC. For example, one, two, . . . or N of the first type transistors MN1-MNN may be selectively turned on. There is a first predetermined relationship between the adjusted ZQ calibration signal ZQSC and the sizes of the first type transistors MN1-MNN. The first predetermined relationship may be generated through experiments or computer simulations.

The SR control circuit 120 of FIG. 2 further uses the inverted adjusted ZQ calibration signal ZQSN to selectively conduct the second transistors MP1-MPN in the first pre-driver 122-11 to the operating voltage terminal, so as to change the driving strength of the first pre-driver 122-11, thereby changing the delay time of the driven sub-enable signal EN1. Namely, the second switching circuit SWC2 selectively turns on one or a combination of the second type transistors MP1-MPN according to the inverted adjusted ZQ calibration signal ZQSN. For example, one, two, . . . or N of the second type transistors MP1-MPN may be selectively turned on. There is a second predetermined relationship between the inverted adjusted ZQ calibration signal ZQSN and the sizes of the second type transistors MP1-MPN. The second predetermined relationship may be generated through experiments or computer simulations.

Based on the PVT characteristics, the boundary angle analysis of the constituent components of the memory device 100 may be classified into features such as a typical-typical (TT) corner, an FF corner, an SS corner, etc. Due to the PVT variation, each corner has different variations in delay time, impedance, driving capability, etc. In the embodiment, in addition to being input to the output stage circuit 130 to compensate for the impedance difference caused by the PVT variation, the ZQ calibration signal 104 is further input to the SR calibration circuit 120 to adjust the delay time for enabling the output stage circuit 130. For example, in an embodiment, when the existing ZQ calibration signal in the third-generation double data rate (DDR3) memory device is used to increase the driving strength of the pre-drivers at different P, V, and T corners, it may enhance the signal strength of the driven sub-enable signals EN1-EN3 provided to the output stage circuit to shorten the circuit delay time; on the other hand, when the driving strength of the pre-drivers is reduced, it may weaken the signal strength of the driven sub-enable signals EN1-EN3 provided to the output stage circuit to increase the circuit delay time. Accordingly, the slew rate of the memory device may be calibrated in the embodiment.

In the embodiment, the enable signal path may further include a resistor-capacitor delay circuit. For example, the enable signal path PE2 includes a resistor-capacitor delay circuit RC1, and the enable signal path PE3 includes a resistor-capacitor delay circuit RC2. An output terminal of the first pre-driver 122-21 is coupled to an input terminal of the second pre-driver 122-22 through the resistor-capacitor delay circuit RC1. An output terminal of the first pre-driver 122-31 is coupled to an input terminal of the second pre-driver 122-32 through the resistor-capacitor delay circuit RC2. The resistor-capacitor delay circuit RC1 includes a resistor R1 and a capacitor C1. The resistor-capacitor delay circuit RC2 includes a resistor R2 and a capacitor C2.

In the embodiment, the variation of the FF corner and the SS corner may be adjusted based on actual testing or computer simulation results. For example, the ZQ calibration signal may include a delay time of a transistor of an output stage circuit (or memory unit) having SS corner or FF corner characteristics. The delay time obtained from the ZQ calibration signal is compared with the driving strength (for example, the size of the transistor) in the pre-driver, and then it is determined whether to increase or decrease the delay time of the output stage circuit 130 by adjusting the driving strength.

In an embodiment, the delay time may be adjusted to be increased or decreased in a level manner. A magnitude of each level may be set according to hardware capabilities, for example, the delay time of the level is nanosecond (ns), microsecond (μs), or picosecond (ps). In other embodiments, a predetermined threshold may be set according to the characteristics of the TT corner, thereby reducing a difference between the slew rates output by the output stages with different corner characteristics.

Table 1 illustrates variations of the slew rate (for example, V/ns) of the data voltage signal at different corners (for example, the TT, SS, FF corners) before and after compensation by the SR control circuit 120. For example, the adjustment of the slew rate is performed by increasing the delay time of the SR control circuit 120 from 166 ps to 172 ps, thereby reducing the slew rate of the output stage circuit with the TT corner characteristics from 3.25 V/ns to 3.11 V/ns. Similarly, the adjustment of the slew rate is performed by decreasing the delay time of the SR control circuit 120 from 216 ps to 150 ps, thereby increasing the slew rate of the output stage circuit with the SS corner characteristics from 2.37 V/ns to 3.28 V/ns. The adjustment of the slew rate is performed by increasing the delay time of the SR control circuit 120 from 108 ps to 161 ps, thereby reducing the slew rate of the output stage circuit with the FF corner characteristics from 4.87 V/ns to 3.25 V/ns. Accordingly, a variation amount of the slew rate is reduced from 2.5 V/ns to 0.17 V/ns. It should be noted that the values shown in Table 1 are only used to illustrate the effects of the embodiments of the disclosure and are not used to limit the disclosure and the embodiments thereof.

TABLE 1

| | | Delay | Slew | Variation |
|---|---|---|---|---|
| | Corner | time (ps) | rate (V/ns) | amount (V/ns) |
| Before | TT | 166 | 3.25 | 2.5 |
| compensation | SS | 216 | 2.37 | |
| | FF | 108 | 4.87 | |
| After | TT | 172 | 3.11 | 0.17 |
| compensation | SS | 150 | 3.28 | |
| | FF | 161 | 3.25 | |

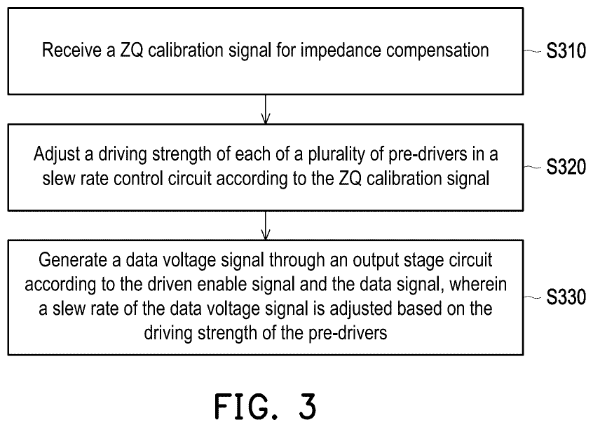

FIG. 3 is a flowchart illustrating a method of controlling slew rate according to an embodiment of the disclosure. The method described in FIG. 3 may be applied to the memory device 100 described in FIG. 1 and FIG. 2. Referring to FIG. 1 and FIG. 3, in step S310, the SR control circuit 120 receives the ZQ calibration signal 104 for impedance compensation. In step S320, the SR control circuit 120 adjusts the respective driving strength of the plurality of pre-drivers 122 in the SR control circuit 120 according to the ZQ calibration signal 104. The pre-drivers 122 generate the driven enable signal 124 based on the data signal 112 provided by the memory array 110. In step S330, the output stage circuit 130 generates the data voltage signal 132 according to the driven enable signal 124 and the data signal 112. The slew rate of the data voltage signal 132 is adjusted based on the driving strength of the pre-drivers 122.

In summary, the memory device for controlling slew rate and the method thereof described in the embodiments of the disclosure correspondingly adjust the respective driving strength of the pre-drivers based on the ZQ calibration signal in the memory device to change the delay time of the data signal and thereby compensate the slew rate of the data voltage signal. The predetermined relationship between the driving strength of the pre-drivers and the ZQ calibration signal may be generated through experiments or computer simulations, and the driving strength may be adjusted by adjusting the sizes of the turned-on transistors in the pre-driver. In other words, the embodiment of the disclosure may adjust the slew rate of the data voltage signal generated by the output stage circuit with different PVT characteristics according to the ZQ calibration signal, thereby reducing the delay time variation of the PVT characteristics on the data voltage signal.

What is claimed is:

1. A memory device, comprising:
a memory array, configured to provide a data signal;
a slew rate control circuit, coupled to the memory array, and comprising a plurality of pre-drivers, wherein the slew rate control circuit receives a ZQ calibration signal and adjusts a driving strength of each of the pre-drivers in the slew rate control circuit according to the ZQ calibration signal, wherein the pre-drivers are configured to generate a driven enable signal according to the data signal; and
an output stage circuit, coupled to the slew rate control circuit, wherein the output stage circuit generates a data voltage signal according to the driven enable signal and the data signal,
wherein a slew rate of the data voltage signal is adjusted based on the driving strength of the pre-drivers.

2. The memory device according to claim 1, wherein the slew rate control circuit uses other signals in the ZQ calibration signal except a least significant bit (LSB) as an adjusted ZQ calibration signal to adjust the driving strength of the each of the pre-drivers in the slew rate control circuit.

3. The memory device according to claim 2, wherein the slew rate control circuit comprises at least one enable signal path, each enable signal path receives the data voltage signal and provides corresponding a plurality of driven sub-enable signals, wherein the driven sub-enable signals serve as the driven enable signal,
wherein the each enable signal path comprises a first pre-driver and a second pre-driver connected in series, the first pre-driver and the second pre-driver have a same circuit structure, and the pre-driver comprises the first pre-driver and the second pre-driver.

4. The memory device according to claim 3, wherein the circuit structure of the first pre-driver and the second pre-driver comprises:
an input terminal;
an output terminal;
a plurality of first type transistors, wherein a control terminal of each of the first type transistors is coupled to the input terminal, and a first terminal of the each of the first type transistors is coupled to the output terminal, wherein the first type transistors are of different sizes;
a first switching circuit, having a control terminal coupled to the adjusted ZQ calibration signal, a first terminal of the first switching circuit coupled to a reference voltage terminal, and a second terminal of the first switching circuit coupled to a second terminal of the each of the first type transistors;
a plurality of second type transistors, wherein a control terminal of each of the second type transistors is coupled to the input terminal, and a first terminal of the each of the second type transistors is coupled to the output terminal, wherein the second type transistors are of different sizes; and
a second switching circuit, having a control terminal coupled to the adjusted ZQ calibration signal that is inverted, a first terminal of the second switching circuit coupled to an operating voltage terminal, and a second terminal of the second switching circuit coupled to a second terminal of the each of the second type transistors.

5. The memory device according to claim 3, wherein the first switching circuit selectively turns on one or a combination of the first type transistors according to the adjusted ZQ calibration signal, and the adjusted ZQ calibration signal and sizes of the first type transistors possess a first predetermined relationship,
the second switching circuit selectively turns on one or a combination of the second type transistors according to the inverted adjusted ZQ calibration signal, and the inverted adjusted ZQ calibration signal and sizes of the second type transistors possess a second predetermined relationship.

6. The memory device according to claim 3, wherein the each enable signal path further comprises a resistor-capacitor delay circuit, and an output terminal of the first pre-driver is coupled to an input terminal of the second pre-driver through the resistor-capacitor delay circuit.

7. The memory device according to claim 3, wherein the output stage circuit comprises a plurality of output buffers, each of the output buffers receives a corresponding driven sub-enable signal to generate a plurality of sub-data voltage signals, and the sub-data voltage signals serve as the data voltage signal.

8. The memory device according to claim 7, wherein the slew rate control circuit changes a delay time of the driven sub-enable signal by changing the driving strength of the each of the pre-drivers, such that a slew rate of the sub-data voltage signal generated by the output buffer is adjusted.

9. The memory device according to claim 1, wherein the output stage circuit has PVT characteristics of a fast-fast (FF) corner and a slow-slow (SS) corner.

10. A method for controlling slew rate, configured to adjust a slew rate of a data voltage signal applied to memory units with different PVT characteristics, the method for controlling slew rate comprising:
receiving a ZQ calibration signal for impedance compensation;
adjusting a driving strength of each of a plurality of pre-drivers in a slew rate control circuit according to the ZQ calibration signal, wherein the pre-drivers are configured to generate a driven enable signal based on a data signal provided by a memory array; and
generating a data voltage signal through an output stage circuit according to the driven enable signal and the data signal, wherein a slew rate of the data voltage signal is adjusted based on the driving strength of the pre-drivers.
